(19) United States
(12) Patent Application Publication
(10) Pub. No.: US 2009/0038544 A1
(43) Pub. Date: Feb. 12, 2009

(54) FILM COATING HOLDER AND FILM COATING DEVICE USING SAME

(75) Inventors: GA-LANE CHEN, Santa Clara, CA (US); SHIH-CHE CHIEN, Tu-Cheng (TW); CHUNG-PEI WANG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignee: HON HAI PRECISION INDUSTRY CO., LTD., Tu-Cheng (TW)

(21) Appl. No.: 12/181,157

(22) Filed: Jul. 28, 2008

(30) Foreign Application Priority Data
Aug. 8, 2007 (CN) 200710201301.0

(51) Int. Cl. C23C 14/00; B05C 13/00

(52) U.S. Cl. 118/50; 118/500

(57) ABSTRACT

A film coating holder includes a main body, a number of workpiece holders, and a number of driving elements. The main body defines a number of separate openings. The workpiece holders are received in the corresponding separate openings, and rotatably mounted on the main body. The driving elements are fixed to the main body and geared with the corresponding workpiece holders.

### BACKGROUND

1. Field of the Invention

The present invention relates to a film coating holder and a film coating device using the same.

2. Description of Related Art

Generally, in a film coating process for workpieces (e.g., lenses), the workpieces are placed on a film coating holder. After a surface of each workpiece is coated, the workpiece is manually turned over on the film coating holder so that another surface of the workpiece can be coated. This process is time-consuming.

Therefore, a new film coating holder and a film coating device using the film coating holder is desired to overcome the shortcomings described above.

### SUMMARY

A film coating holder includes a main body, a number of workpiece holders, and a number of driving elements. The main body defines a number of separate openings. The workpiece holders are received in the separate openings, and rotatably mounted on the main body. The driving elements are fixed to the main body and geared with the workpiece holders.

Other advantages and novel features of the present invention will become more apparent from the following detailed description of an embodiment/embodiments when taken in conjunction with the accompanying drawings, in which:

### BRIEF DESCRIPTION OF THE DRAWINGS

FIG. 1 is an isometric view of one embodiment of a film coating holder; and

FIG. 2 is a schematic, isometric view of one embodiment of a film coating device using the film coating holder of FIG. 1.

### DETAILED DESCRIPTION

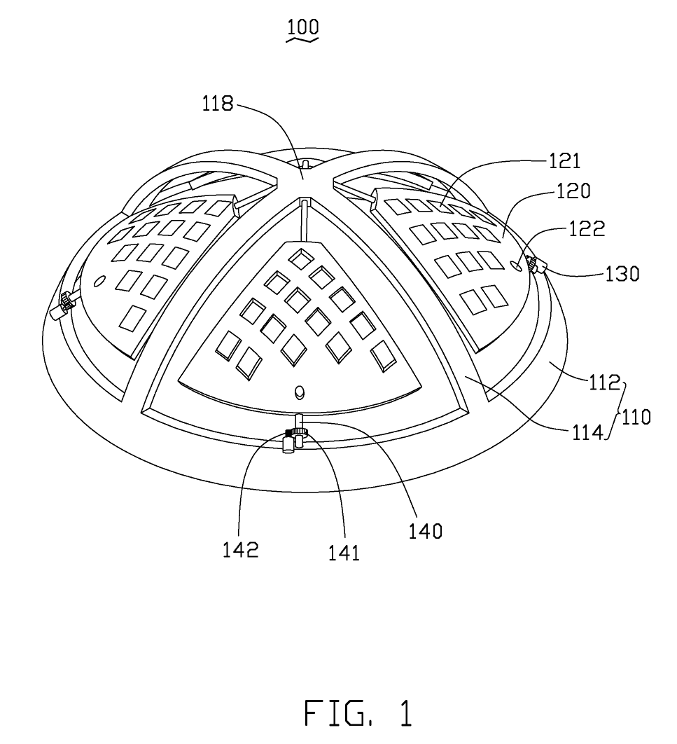

Referring to FIG. 1, a film coating holder 100 includes a main body 110, a plurality of workpiece holders 120 rotatably mounted on the main body 110, and a plurality of driving elements 130 geared with the corresponding workpiece holders 120. The main body 110 and the workpiece holders 120 are made of a highly thermally conductive metallic material, such as copper, aluminum, or stainless steel.

In the embodiment of FIG. 1, the main body 110 is umbrella-shaped and includes a circular frame 112 and four arc-shaped arms 114. An end of each arc-shaped arm 114 is connected to the circular frame 12, and the other end of each arc-shaped arm 114 is connected to each other, such that the circular frame 112 and the four arc-shaped arms 114 cooperatively define four separate openings 116 and form an upper portion 118. The openings 116 are uniformly defined between the circular frame 112 and the arc-shaped arms 114. Each opening 116 is sector-shaped and axisymmetrical. The workpiece holders 120 are received in the openings 116.

Each driving element 130 corresponding to each opening 116 is fixed to the circular frame 112. The driving element 130 is configured to rotate the workpiece holder. The driving element 130 can be an electromagnetic pump, a magnetic current motor, or a magnetorheological fluid damper. A wireless controller (not shown) may be coupled to the driving element 130 to control the driving element 130 wirelessly.

Each workpiece holder 120 defines a number of through holes 121 for receiving workpieces (not shown), such that both surfaces of each workpiece can be coated. Each workpiece holder 120 corresponding to each opening 116 is sector-shaped, axisymmetrical, and includes a rotating shaft 140 extending from opposite sides of each workpiece holder 120. The rotating axis of the rotating shaft 140 is along the symmetrical axis of the opening 116 and the workpiece holder 120, such that the workpiece holder 120 does not contact the main body 110 when the workpiece holder 120 is rotated about the rotating axis of the rotating shaft. An end of the rotating shaft 140 is rotatably connected to the upper portion 118 of the main body 110, and the other end of the rotating shaft 140 is rotatably connected to the circular frame 112 adjacent to each driving element 130. Specifically, the other end of the rotating shaft 140 rotatably connected to the circular frame 112 is provided with a first gear 141, and the driving element 130 is provided with a second gear 142 configured for engaging with the first gear 141 such that each workpiece holder 120 is driven by the driving element 130 to rotate. Thus, the workpieces received in the through holes 121 can be turned over by the rotation of the workpiece holders 120 by the driving elements, eliminating time spent manually rotating the workpiece surfaces.

In the embodiment of FIG. 1, the workpiece holders 120 are mounted on the main body 110 in a symmetrical-distribution fashion. Each workpiece holder 120 has a mirrored image about a central axis of the main body 110. Each workpiece holder 120 further defines an aperture 122.

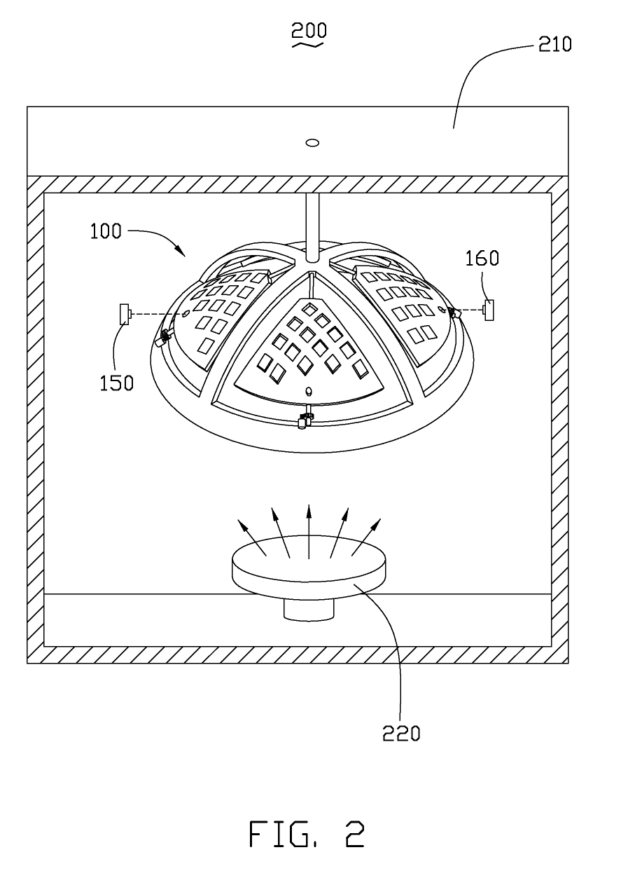

Referring also to FIG. 2, a film coating device 200 includes a vacuum chamber 210, which houses a film coating source 220, the film coating holder 100 facing the film coating source 220, a light emitting unit 150, and a light receiving unit 160. The vacuum chamber 210 is configured to conduct a coating process in a vacuum environment and prevent contaminants from entering the chamber and contaminating the workpieces.

The light emitting unit 150 and the light receiving unit 160 are positioned outside of the film coating holder 100, and horizontally aligned with the apertures 122 of two opposite mirrored holders 120 so that light emitted from the light emitting unit 150 may pass through the apertures 122 of the mirrored holders 120 to the light receiving unit 160. The light receiving unit 160 is configured to determine if the workpiece holders 120 between the light emitting unit 150 and the light receiving unit 160 are properly aligned with each other based on the intensity of the received light. In one embodiment, the light receiving unit 160 may output an electrical signal indicating the intensity of the received light. For example, the light emitting unit 150 may be an infrared light source, and the light receiving unit 160 may be an infrared light receiver capable of converting a light signal into an electrical signal.

In the embodiment of FIG. 2, film coating process, the light emitting unit 150 and the light receiving unit 160 are horizontally aligned with the apertures 122. The light emitting unit 150 emits light, the light passes through the apertures 122 to the light receiving unit 160, and the light receiving unit 160 receives the light and outputs an initial output electrical signal based on the received light intensity.

After a surface of the workpiece is coated, each driving element 130 is activated to drive the corresponding workpiece holder 120 to rotate 180 degrees so that another surface of the workpiece can be coated. The film coating process may be monitored in one aspect, according to an output electrical signal of the light receiving unit 160 to determine if the rotated workpiece holder 120 is still aligned to another rotated workpiece holder 120. If the output electrical signal is approximately the same as the initial output electrical signal, the rotated workpiece holders 120 are properly aligned. If the output electrical signal is different from the initial output electrical signal, the rotated workpiece holders 120 are not in the proper rotational position. Thus, rotations of the mirrored workpiece holders 120 can be monitored.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A film coating holder comprising:
a main body defining a plurality of separate openings;
a plurality of workpiece holders, wherein each workpiece holder is received in each corresponding separate openings and each workpiece holders is rotatably mounted on the main body; and
a plurality of driving elements fixed to the main body, wherein each driving element is geared with each corresponding workpiece holder.

2. The film coating holder as claimed in claim 1, wherein each driving element is selected from the group consisting of an electromagnetic pump, a magnetic current motor, and a magnetorheological fluid damper.

3. The film coating holder as claimed in claim 2, further comprising a plurality of wireless controllers, wherein each wireless controller is coupled to each driving element to control the driving element.

4. The film coating holder as claimed in claim 1, wherein a material of the main body is selected from the group consisting of copper, aluminum and stainless steel.

5. The film coating holder as claimed in claim 1, wherein a material of each workpiece holder is selected from the group consisting of copper, aluminum and stainless steel.

6. The film coating holder as claimed in claim 1, wherein the plurality of the workpiece holders are mounted on the main body in a symmetrical-distribution fashion.

7. The film coating holder as claimed in claim 6, wherein each workpiece holder defines a through hole, wherein the through hole of one of the plurality of workpiece holders is aligned with the through hole of another of the plurality of workpiece holders.

8. A film coating device comprising:
a vacuum chamber;
a film coating source received in the vacuum chamber; and
a film coating holder received in the vacuum chamber and facing the film coating source, the film coating holder comprising:
a main body defining a plurality of separate openings;
a plurality of workpiece holders, wherein each workpiece holder is received in each corresponding separate openings and each workpiece holders is rotatably mounted on the main body; and
a plurality of driving elements fixed to the main body, wherein each driving element is geared with each corresponding workpiece holder.

9. The film coating device as claimed in claim 8, wherein each driving element is selected from the group consisting of an electromagnetic pump, a magnetic current motor, and a magnetorheological fluid damper.

10. The film coating device as claimed in claim 8, wherein a material of the main body is selected from the group consisting of copper, aluminum and stainless steel.

11. The film coating device as claimed in claim 8, wherein a material of each workpiece holder is selected from the group consisting of copper, aluminum and stainless steel.

12. The film coating device as claimed in claim 8, wherein the plurality of the workpiece holders are mounted on the main body in a symmetrical-distribution fashion.

13. The film coating device as claimed in claim 12, wherein each workpiece holder defines a through hole, wherein the through hole of one of the plurality of workpiece holders is aligned with the through hole of another of the plurality of workpiece holders.

14. The film coating device as claimed in claim 13, further comprising a light emitting unit and a light receiving unit outside of the film coating holder, wherein the light emitting unit, the through holes of two of the plurality of workpiece holders, and the light receiving unit are in alignment.
